(19) United States
(12) Patent Application Publication
(10) Pub. No.: US 2015/0008574 A1
(43) Pub. Date: Jan. 8, 2015

(54) SEMICONDUCTOR DEVICE AND METHOD FOR MANUFACTURING SEMICONDUCTOR DEVICE

(71) Applicant: FUJI ELECTRIC CO., LTD., Kawasaki-shi (JP)

(72) Inventors: Hiromichi GOHARA, Matsumoto-shi (JP); Akira MOROZUMI, Okaya-shi (JP); Takafumi YAMADA, Matsumoto-shi (JP)

(21) Appl. No.: 14/492,790

(22) Filed: Sep. 22, 2014

Related U.S. Application Data
(63) Continuation of application No. PCT/JP2013/071881, filed on Aug. 13, 2013.

(30) Foreign Application Priority Data
Sep. 19, 2012 (JP) 2012-206267

(51) Int. Cl. H01L 23/473; H01L 23/00; H01L 23/12

(52) U.S. Cl. CPC H01L 23/473; H01L 23/12; H01L 24/81; H01L 2224/81085
USPC 257/714; 438/122

(57) ABSTRACT

A semiconductor device includes an insulating substrate; a semiconductor element mounted on the insulating substrate; and a cooler cooling the semiconductor element. The cooler includes a heat radiating substrate bonded to the insulating substrate; a plurality of fins provided on a surface opposite to a surface bonded with the insulating substrate of the heat radiating substrate; and a case accommodating the fins, and including an inlet and an outlet for a coolant. Upper end portions of side walls of the case include cutaways to arrange end portions of the heat radiating substrate. The heat radiating substrate is liquid-tightly bonded to the case.

### CROSS REFERENCE TO RELATED APPLICATION

The present application is a continuation application of an International Application No. PCT/JP2013/071881 filed Aug. 13, 2013, and claims priority from Japanese Application No. 2012-206267 filed Sep. 19, 2012.

### TECHNICAL FIELD

The present invention relates to a semiconductor device provided with a cooler for cooling a semiconductor element, and to a method for manufacturing a semiconductor device.

### BACKGROUND ART

Equipment using a motor, typically a hybrid vehicle or an electric automobile, uses a power conversion device in order to save energy. A semiconductor module is used widely in a power conversion device of this kind. A semiconductor module which constitutes a control device for saving energy in this way is provided with a power semiconductor element for controlling large current. A normal power semiconductor element generates heat when controlling a large current, and the amount of heat generated increases as the size of the power conversion device becomes more compact and the output becomes higher. Therefore, in a semiconductor module provided with a plurality of power semiconductor elements, the cooling method for the module presents a major problem.

A liquid cooler has been used conventionally as a cooler installed on a semiconductor module in order to cool the semiconductor module. In order to improve the cooling efficiency, a liquid cooler employs various modifications, such as increasing the flow volume of the coolant, forming the heat radiating fins (cooling bodies) provided on the cooler in a shape having good heat transmissivity, or using a material having high thermal conductivity to make the fins, and so on.

Furthermore, a semiconductor device provided with heat radiating fins may employ, for example, a structure in which the power semiconductor element and the heat radiating substrate are bonded via an insulating substrate. In the semiconductor device having a structure of this kind, improvement in the heat radiating properties is enhanced and the cooling efficiency can be improved, by reducing the whole thickness of the heat radiating substrate. Consequently, it is possible to effectively lower the increase in the temperature of the power semiconductor. However, there is a large difference between the coefficients of linear expansion of the ceramic material of the insulating substrate and the base material of the heat radiating substrate, and therefore the heat generated in the power semiconductor element generates deformation of the heat radiating substrate. Therefore, in a semiconductor device having a structure of this kind, when the whole thickness of the heat radiating substrate is reduced, deformation occurs in the heat radiating substrate due to the effects of the coefficient of linear expansion. Consequently, there is a problem in that the reliability of the bonding portion between the insulating substrate and the heat radiating substrate is reduced, and so on.

A structure has been proposed (Patent Document 1), in which a conducting layer is formed on one surface of a ceramic insulating substrate, and a heat radiating layer which also serves as a fin base of substantially the same thickness as the conducting layer is formed on the other surface thereof, the thickness of the outer circumferential side of the heat radiating layer being thickened and reinforced compared with the fin base section, thereby suppressing deformation.

Patent Document 1: Japanese Patent Application Publication No. 2009-26957 (see paragraph [0015] and FIG. 2)

However, with the structure described in Patent Document 1, there is a problem of deformation due to external force, since the thickness of the heat radiating layer which also serves as a fin base is substantially the same as that of the conducting layer.

Furthermore, with a structure in which the power semiconductor element and the heat radiating substrate for heat radiation are bonded via an insulating substrate, and the thickness of the external circumferential portion of the heat radiating substrate is maintained while only the thickness of the bonding portion with the insulating substrate is reduced, there is larger burden in terms of fabrication costs, due to the problems caused by the more complicated structure, and so on.

Moreover, improvements in the materials of the bonded heat radiating substrate and insulating substrate, and improvements by providing a stress relieving material in the bonding portion therebetween, can be envisaged, but all of these affect costs, due to increasing the processing work involved, and therefore it is difficult to simultaneously achieve both improvement in the heat radiating properties and improvement in reliability, while minimizing the effect on costs.

### DISCLOSURE OF THE INVENTION

The present invention has been made in view of the problems described above, and an object thereof is to provide a semiconductor device having good heat radiating properties and high reliability while suppressing increase in the burden of fabrication costs, and a method for manufacturing a semiconductor device.

The semiconductor device and the method for manufacturing a semiconductor device described below are provided in order to achieve the aforementioned object.

The semiconductor device includes: an insulating substrate, a semiconductor element mounted on the insulating substrate, and a cooler cooling the semiconductor element. The cooler includes a heat radiating substrate bonded with the insulating substrate, a plurality of fins provided on a surface opposite to a surface bonded with the insulating substrate of the heat radiating substrate, and a case accommodating the fins and having an inlet and an outlet for a coolant. End portions of the heat radiating substrate are arranged in cutaways provided in upper end portions of side walls of the case, such that the heat radiating substrate and the case are liquid-tightly bonded.

The method for manufacturing this semiconductor device, which includes an insulating substrate, a semiconductor element mounted on the insulating substrate, and a cooler cooling the semiconductor element, comprises a step of bonding a heat radiating substrate and a case of the cooler, which has the heat radiating substrate, a plurality of fins and the case. The case is prepared so as to have cutaways formed in upper ends of side walls of the case, and end portions of the heat radiating substrate are arranged in the cutaways of the case, such that the heat radiating substrate and the case are bonded in a liquid-tight fashion.

According to the present invention, since the cutaways are provided in the upper end portions of the case of the cooler, and a heat radiating substrate matching these cutaways is provided so as to close off the upper end opening of the case, then fabrication is simplified and increase in the manufacturing costs can be suppressed, while maintaining good heat radiating properties of the heat radiating substrate which has a prescribed thickness.

### BRIEF DESCRIPTION OF THE DRAWINGS

FIG. 1 is an external perspective diagram showing one example of a semiconductor device according to the present invention.

FIG. 2 is a cross-sectional diagram along the line II-II of the semiconductor device in FIG. 1.

FIG. 3 is a diagram showing one example of a power conversion circuit composed as a semiconductor module.

FIGS. 4A to 4C are diagrams illustrating three fin shapes, wherein FIG. 4A is a perspective diagram showing blade fins, FIG. 4B is a perspective diagram showing pin fins having round rod-shaped pins, and FIG. 4C is a perspective diagram showing pin fins having square rod-shaped pins.

FIG. 5 is a perspective diagram showing the principal composition of a case of a cooler.

FIG. 6 is a cross-sectional diagram showing another example of a semiconductor device according to the present invention.

FIG. 7 is a cross-sectional diagram of a conventional semiconductor module structure, for illustrating a conventional semiconductor module as a first Comparative Example.

FIG. 8 is a diagram showing the results of a comparison of thermal resistance values according to the configuration, in a semiconductor device of the Comparative Example.

FIG. 9 is a diagram showing the results of a comparison of thermal resistance values according to the configuration, in a semiconductor device of an embodiment.

### BEST MODE FOR CARRYING OUT THE INVENTION

Embodiments of a semiconductor device and a method for manufacturing a semiconductor device according to the present invention are described here in concrete terms with reference to the drawings.

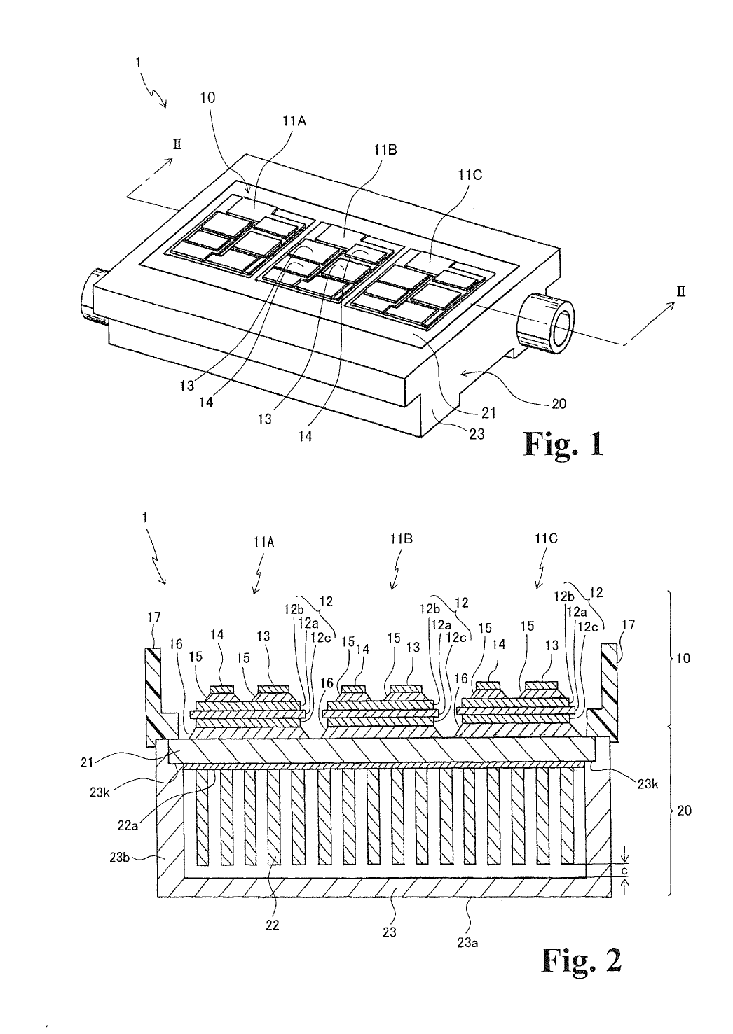

The semiconductor device 1 of one embodiment of the present invention which is depicted in a perspective view in FIG. 1 and a cross-sectional view in FIG. 2 is provided with a semiconductor module 10 and a cooler 20 for cooling the semiconductor module 10. In the illustrated embodiment, the semiconductor module 10 has a plurality of circuit element sections 11A, 11B and 11C which is arranged on the cooler 20. The semiconductor module 10 is constituted, for example, by a three-phase inverter circuit based on the circuit element sections 11A, 11B and 11C.

Each of the circuit element sections 11A, 11B and 11C has an insulating substrate 12, as shown in FIG. 2. The insulating substrate 12 is constituted by an insulating layer 12a made from a plate having electrical insulating properties, and conducting layers 12b and 12c which are formed respectively on both surfaces of the insulating layer 12a. For the insulating layer 12a of the insulating substrate 12, it is possible to use a ceramic substrate, such as aluminum nitride, aluminum oxide, or the like. The conducting layers 12b and 12c of the insulating substrate 12 can be formed by using a conductive metal foil of copper or aluminum (for example, copper foil or aluminum foil).

The conducting layer 12b of the insulating substrate 12 is a conducting layer in which a circuit pattern is formed, and semiconductor elements 13 and 14 are bonded on the conducting layer 12b via a bonding layer 15, made of solder, or the like. The semiconductor elements 13 and 14 are electrically connected directly by the circuit pattern of the conducting layer 12b, or via a wire (not illustrated). The exposed surfaces of the conducting layers 12b and 12c of the insulating substrate 12, and the wire surfaces which electrically connect the semiconductor elements 13 and 14 and the conducting layer 12b, may have a protective layer formed thereon by nickel plating, or the like, in order to protect these surfaces from soiling, corrosion, external forces, and the like.

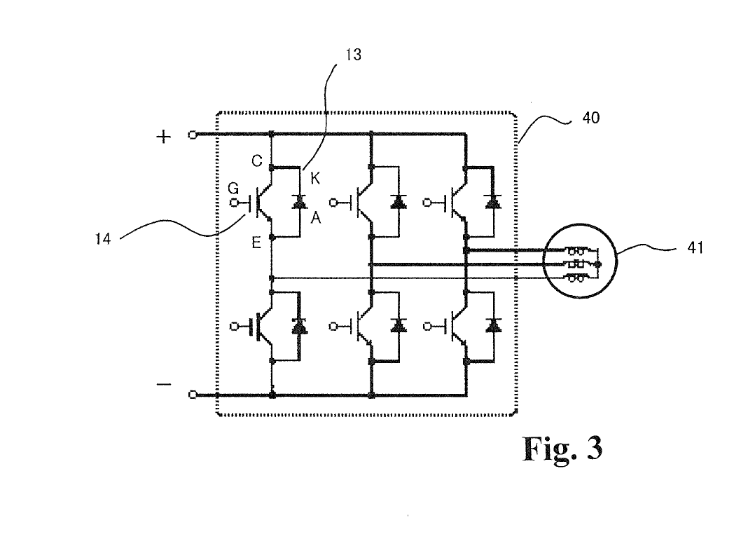

For the semiconductor elements 13 and 14 which are mounted on the insulating substrate 12 in this way, a power semiconductor element is used in the present embodiment, which is illustrated. As shown by the circuit diagram in FIG. 3, the semiconductor module 10 constitutes a three-phase inverter circuit 40 as an example of a power conversion circuit. In the inverter circuit 40 shown in FIG. 3, a three-phase AC motor 41 is connected by taking one semiconductor element 13 as a free-wheeling diode (FWD) and taking the other semiconductor element 14 as an insulated gate bipolar transistor (IGBT).

In the description given above, an example is described in which three circuit element sections 11A to 11C are provided in the semiconductor module 10. However, the number of circuit element sections can be modified, as appropriate, in accordance with the circuit, application or function of the semiconductor module 10, and is not necessarily limited to three. The semiconductor module 10 is provided with a resin case 17 so as to surround the circuit element sections 11A to 11C. This resin case 17 is not depicted in FIG. 1 in order to make the drawing easier to understand.

The side of the other conducting layer 12c of the insulating substrate 12 on which the semiconductor elements 13 and 14 have been mounted is bonded to a heat radiating substrate 21 of the cooler 20, via a bonding layer 16. In this way, the insulating substrate 12 and the semiconductor elements 13 and 14 are connected so as to be able to conduct heat to the cooler 20.

The cooler 20 has a heat radiating substrate 21, a plurality of fins 22 fixed to the heat radiating substrate 21, and a case 23 which accommodates the fins 22. The fins 22 are used as heat-radiating plates, in other words, as a heat sink.

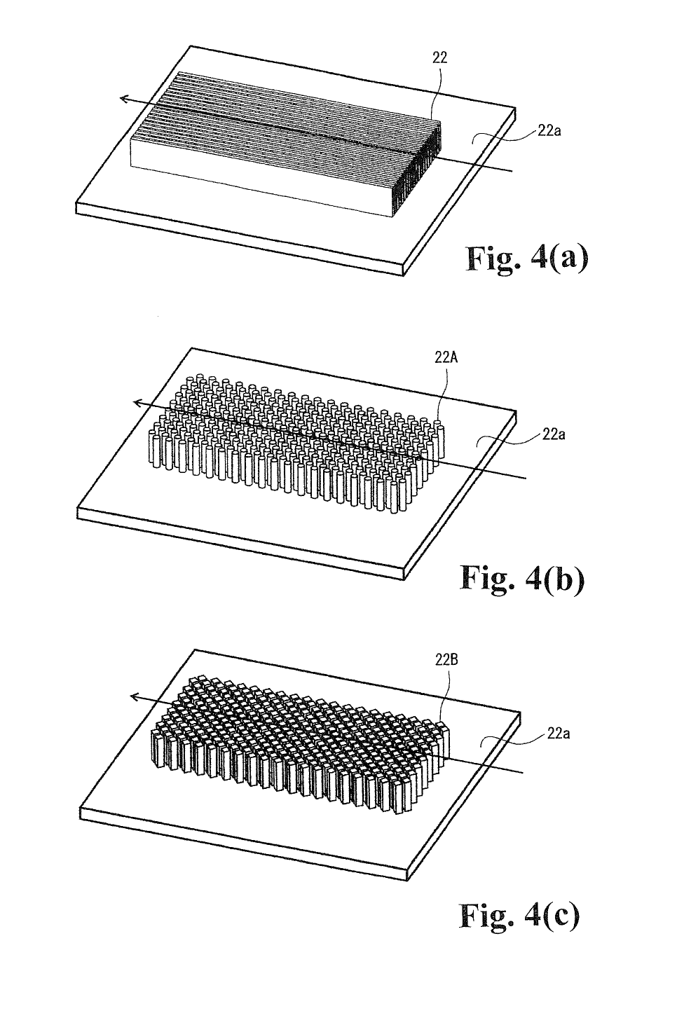

The fins 22 can be formed as blade fins in which a plurality of blade-shaped fins is provided in mutually parallel arrangement, as shown in FIG. 4A, for example. Instead of these blade fins, it is also possible to use pin fins in which a plurality of pins 22A having a round rod shape as shown in FIG. 4B, or pins 22B having a square rod shape as shown in FIG. 4C, is arranged at intervals apart. With regard to the shape of the fins 22, it is possible to use various fin shapes other than blade fins or pin fins. However, desirably, the fins 22 have a shape which produces a small pressure loss with respect to the coolant, since the fins 22 create a resistance to the coolant when the coolant flows inside the cooler 20. FIGS. 4A, 4B and 4C show arrows indicating the direction of flow of the coolant.

Desirably, the shape and dimensions of the fins 22 are set, as appropriate, by taking account of the input conditions of the coolant to the cooler 20 (in other words, the pump performance, etc.), the type and characteristics of the coolant (in particular, the viscosity, etc.), and the target amount of heat to be removed, and other factors. Furthermore, the fins 22 are formed to dimensions (a height) whereby a prescribed clearance C is present between the front end of the fins 22 and the bottom wall 23a of the case 23, when the fins 22 are accommodated in the case 23. However, a composition having a zero clearance is not excluded.

As shown in FIG. 2, for example, the fins 22 having the shape shown in FIG. 4 are installed and fixed in a prescribed region of the heat radiating substrate 21 so as to extend in a perpendicular direction from the surface of the heat radiating substrate 21, and are thereby integrated with the heat radiating substrate 21. Desirably, the region of the heat radiating substrate 21 where the fins 22 are installed is the region obtained when the region where the semiconductor elements 13 and 14 are mounted on the insulating substrate 12 is projected in the thickness direction of the heat radiating substrate 21, when the heat radiating substrate 21 has been bonded to the insulating substrate 12. In other words, desirably, the region of the heat radiating substrate 21 is a region including the region directly below the semiconductor elements 13 and 14.

In FIG. 2, the plurality of fins 22 is integrated by being bonded previously to a plate-shaped fin base material 22a, and the heat radiating substrate 21 and the fins 22 are integrated by bonding the surface of the fin base material 22a of the integrated fins 22, with the surface of the heat radiating substrate 21. By this means, the fins 22 are accommodated inside the case 23, in a state of being held by the fin base material 22a and the heat radiating substrate 21.

In FIG. 2, the fins 22 have a fin base material 22a, but the fin base material 22a is not essential. For example, the fins 22 can be formed by integrated casting with the heat radiating substrate 21, by a die casting process. Furthermore, the fins 22 can also be bonded directly to the heat radiating substrate 21 by brazing or various other types of welding method, whereby the fins 22 can be formed in an integrated fashion with the heat radiating substrate 21. Moreover, it is also possible to form a projection on one surface of the heat radiating substrate 21 by die casting or press forging, so as to assume the approximate shape of a heat sink, and to then fabricate this projection into a desired fin shape by a cutting process or wire cutting method. Furthermore, it is also possible to form the heat radiating substrate 21 and the fins 22 in an integrated fashion, by a press forging method only.

The outer shape of the heat sink formed by the fins 22 is a substantially cuboid shape, and desirably, is a cuboid shape, although the shape may be chamfered or modified within a range that does not impair the beneficial effects of the present invention.

The fins 22 and the heat radiating substrate 21 are desirably made from a material having high thermal conductivity, and a metal material is especially desirable. For example, it is possible to form the fins 22 and the heat radiating substrate 21 by using a metal material, such as aluminum, aluminum alloy, copper, copper alloy, or the like; for instance, A1050, A6063, or the like, is desirable. More desirably, it is possible to use aluminum which has a thermal conductivity of 200 W/mk or above. The fins 22 and the heat radiating substrate 21 may be made of the same metal material, or may be made of different metal materials. For the fin base material 22a when the fins 22 are bonded to the fin base material 22a, it is possible to use a metal material, for example.

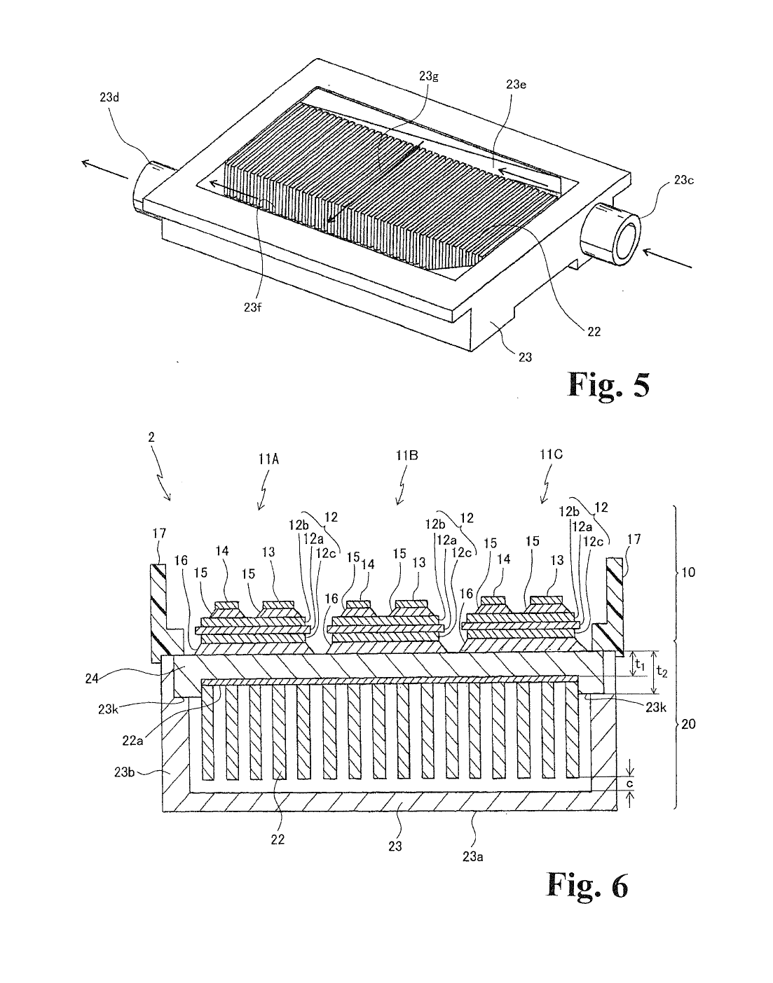

The case 23 which accommodates the fins 22 has a box-shaped form having a bottom wall 23a and side walls 23b provided at the perimeter edges of the bottom wall 23a, the top thereof being open. As shown in FIG. 5, the case 23 has a substantially cuboid outer shape, but the case 23 is not limited to having a substantially cuboid outer shape.

As shown in FIG. 5, in the case 23, an inlet 23c for introducing a coolant inside the case 23 is provided in the vicinity of a corner portion of one side wall 23b of the shorter side walls 23b, and an outlet 23d for discharging coolant to the exterior from the inside of the case 23 is provided in the vicinity of the opposing corner of the other side wall 23b of the shorter side walls 23b. When the fins 22 are accommodated in the case 23, a coolant inlet flow channel 23e is formed along the side wall 23b of the longer edge of the case 23, from the inlet 23c, a coolant discharge flow channel 23f is formed along the side wall 23b of the longer edge of the case 23, from the outlet 23d, and a cooling flow channel 23g is formed in the gaps between the fins 22, between the coolant inlet flow channel 23e and the coolant discharge flow channel 23f. In FIG. 5, the cutaways 23k are not depicted, in order make the drawing easier to understand.

Similarly to the fins 22 and the heat radiating substrate 21, the material used for the case 23 must be selected in accordance with the structure, for instance, a material having high thermal conductivity, a material which incorporates the peripheral parts when forming a unit, and so on. Taking account of the thermal conductivity, a material such as A1050 or A6063 is desirable, and if it is necessary to seal the case 23 with peripheral members, and especially, fixing parts and/or an inverter case accommodating the power module, then a material such as ADC 12 or A6061, or the like, is desirable. Furthermore, if the case 23 is manufactured by die-casting and is required to have thermal conductivity, then it is possible to employ a DMS series material, which is a high-thermal-conductivity aluminum alloy for die-casting manufactured by Mitsubishi Plastics Inc. When the case 23 is formed using a metal material of this kind, it is possible to form the inlet 23c, the outlet 23d and the flow channel inside the case 23, by die-casting, for example. The case 23 can use a metal material which contains carbon fillers. Furthermore, depending on the type of coolant, and the temperature of the coolant flowing inside the case 23, it is also possible to use a ceramic material or a resin material, or the like, but if the case 23 and the heat radiating substrate 21 are bonded by a friction stir welding method as described below, then a ceramic material or a resin material cannot be used.

The upper ends of the side walls 23b of the case 23 and the end portions of the heat radiating substrate 21 are bonded in a liquid-tight fashion along the side walls 23b. By this means, the coolant is prevented from leaking out from the bonding portion between the case 23 and the heat radiating substrate 21, when a flow of coolant is generated in which the coolant introduced into the case 23 from the inlet 23c passes along the coolant inlet flow channel 23e, the cooling flow channel 23g and the coolant discharge flow channel 23f, and is discharged from the outlet 23d.

A concrete example of the liquid-tight bonding according to the present embodiment will now be described. As shown in FIG. 2, cutaways 23k having an L-shaped cross-section are formed in the upper ends of the side walls 23b, and the heat radiating substrate 21 has end portions of a shape and size that match these cutaways 23k of the case 23. The cutaways 23k of the case 23 are formed to dimensions whereby the upper end surfaces of the side walls 23b of the case 23 and the upper surface of the heat radiating substrate 21 are in the same plane, when the end portions of the heat radiating substrate 21 are arranged in the cutaways 23k. The end portions of the heat radiating substrate 21 are arranged so as to be mounted on the cutaways 23k of the upper ends of the side walls 23b of the case 23. By bonding the cutaway 23k portions of the side walls 23b and the end portions of the heat radiating substrate 21, by a commonly known method, the heat radiating substrate 21 and the case 23 are bonded in a liquid-tight fashion.

The bonding method used between the upper ends of the side walls 23b of the case 23 and the end portions of the heat radiating substrate 21 can employ a commonly known method, such as brazing or soldering, but it is more desirable to employ a friction stir welding method. By using the friction stir welding method, it is possible to create a reliable liquid-tight bond between the upper ends of the side walls 23b of the case 23 and the end portions of the heat radiating substrate 21. If the friction stir welding method is used to create the bonds, then at the bonding interface between the cutaway 23k of the side wall 23b and the heat radiating substrate 21, a bond is created in a portion extending in the thickness direction of the heat radiating substrate away from the upper surface of the case 23. By bonding this portion, it is possible to carry out bonding by applying the friction stir welding tool from above towards the bonding interface between the case 23 and the heat radiating substrate 21, while supporting the bottom surface of the case 23, and therefore a reliable bond can be achieved. Moreover, by using the friction stir welding method to create the bonds, it is possible to use a high-thermal-conductivity material, such as an A6063 and DMS series alloy, or HT-1, which is a high-thermal-conductivity aluminum alloy for die-casting manufactured by Daiki Aluminum Industry Co., Ltd., for example, as the material of the heat radiating substrate 21 and the case 23, thereby improving the radiation of heat.

Forming the cutaways 23k in the case 23 hardly gives rise to any increase in costs. Furthermore, since the heat radiating substrate 21 can be formed as a flat plate shape, in other words, no particular fabrication is necessary to alter the thickness of the end portions of the heat radiating substrate 21 or the portion thereof to which the fins 22 are bonded, compared to the other portions of the substrate, then the manufacturing process is simple and there is no increase in costs. Moreover, by forming the heat radiating substrate 21 as a flat plate shape, it is possible to form very fine fins 22 very accurately, in a relatively simple fashion, in cases where the heat radiating substrate 21 and the fins 22 are formed in an integrated fashion by die-casting, press forging, or a cutting process. Furthermore, the heat radiating substrate 21 can be made reliable with respect to deformation, and can be given good heat radiating properties, by having a prescribed thickness. The thickness of the heat radiating substrate 21 is desirably 1 to 3 mm in the region where the fins 22 are bonded, for example.

When using the cooler 20, a pump (not illustrated) is connected to the inlet 23c, a heat exchanger (not illustrated) is connected to the outlet 23d, and a closed-loop coolant flow path including the cooler 20, the pump and the heat exchanger is constituted. The coolant is circulated compulsorily inside the closed loop of this kind, by a pump. The coolant can use water or a long-life coolant (LLC), or the like.

In the semiconductor device 1 according to the present embodiment, when the power conversion circuit shown in FIG. 3 is operating, the heat generated by the semiconductor elements 13 and 14 of the circuit element sections 11A to 11C shown in FIG. 1 and FIG. 2 is transmitted to the heat radiating substrate 21 which is bonded to the insulating substrate 12, and is transmitted to the fins 22 which are bonded to the heat radiating substrate 21. In the case 23, since a cooling flow channel 23g is formed in the gaps between the fins 22 as described above, the heat sink constituted by the fins 22 is cooled due to the flow of coolant in the cooling flow channel 23g. In this way, the heat generated by the circuit element sections 11A to 11C is cooled by the cooler 20.

FIG. 6 shows a cross-sectional view of a semiconductor device 2 according to a further embodiment of the present invention. In the semiconductor device 2 shown in FIG. 6, members which are the same as the semiconductor device 1 in FIG. 2 are labelled with the same reference numerals, and duplicated description of these members is omitted below. In the semiconductor device 2 in FIG. 6, the cross-sectional shape of the heat radiating substrate 24 which constitutes the cooler 20 has an L-shaped form and therefore differs from the heat radiating substrate 21 of the semiconductor device 1 in FIG. 2. The portion (fin region) of the heat radiating substrate 24 where the fins 22 are bonded to the heat radiating substrate 24 via the fin base material 22a has a thickness t1 which is less than the thickness t2 of the portion (peripheral region) surrounding the fin region. The case 23 has cutaways 23k formed in the upper ends of the side walls 23b so as to have an L-shaped cross-section. The cutaways 23k are formed to dimensions whereby the upper end surfaces of the side walls 23b of the case 23 and the upper surface of the heat radiating substrate 24 are in the same plane, when the end portions of the heat radiating substrate 24 are arranged so as to be placed on the cutaways 23k of the case 23. The upper ends of the side walls 23b of the case 23 and the end portions of the heat radiating substrate 24 are bonded in a liquid-tight fashion along the side walls 23b, by a commonly known method.

The bonding method used between the upper ends of the side walls 23b of the case 23 and the end portions of the heat radiating substrate 24 can employ a commonly known method, such as brazing or soldering, but it is more desirable to employ a friction stir welding method. By using the friction stir welding method, it is possible to create a reliable liquid-tight bond between the upper ends of the side walls 23b of the case 23 and the end portions of the heat radiating substrate 24. If the friction stir welding method is used to create the bonds, then at the bonding interface between the cutaway 23k of the side wall 23b and the heat radiating substrate 24, a bond is created in a portion extending in the thickness direction of the heat radiating substrate away from the upper surface of the case. By bonding this portion, it is possible to carry out bonding by applying the friction stir welding tool from above towards the bonding interface between the case 23 and the heat radiating substrate 24, while supporting the bottom surface of the case 23, and therefore a reliable bond can be achieved. Moreover, by using the friction stir welding method to create the bonds, it is possible to use a high-thermal-conductivity material, such as an A6063 and DMS series alloy, or HT-1, which is a high-thermal-conductivity aluminum alloy for die-casting manufactured by Daiki Aluminum Industry Co., Ltd., for example, as the material for the heat radiating substrate 24 and the case 23, thereby improving the radiation of heat.

In the semiconductor device 2 according to the present embodiment shown in FIG. 6, forming the cutaways 23k in the case leads to hardly any increase in costs. Moreover, the fin region of the heat radiating substrate 24 is thinner than the peripheral region, and therefore the heat radiating properties can be improved. Furthermore, the heat radiating substrate 24 can be made reliable with respect to deformation, due to the peripheral region having a prescribed thickness. The thickness of the heat radiating substrate 24 is desirably 1 to 3 mm in the region where the fins 22 are bonded, for example.

Next, one embodiment of the method for manufacturing a semiconductor device according to the present invention will be described.

In manufacturing the semiconductor device 1 shown in FIG. 1 and FIG. 2, a step of bonding the heat radiating substrate 21 of the cooler 20 and the case 23 is included. Before carrying out this step, the insulating substrate 12 and the fins 22 are bonded to the heat radiating substrate 21, and furthermore, the semiconductor elements 13 and 14 are mounted on top of the insulating substrate 12.

In the step of bonding the heat radiating substrate 21 of the cooler 20 and the case 23, firstly, a case 23 is prepared which is formed with a shape having a cutaway 23k about the whole circumference of the upper ends of the side walls 23b. If the case 23 is manufactured by die-casting, then the cutaway may be formed during this die-casting. However, it is also possible to form the cutaway by fabrication, such as a cutting process, after die-casting. By arranging the end portions of the heat radiating substrate 21 in the cutaways 23k of the case 23, and bonding the portions of the cutaway 23k and the end portions of the heat radiating substrate 21, by a commonly known method, the heat radiating substrate 21 and the case 23 are bonded in a liquid-tight fashion. This liquid-tight bonding is desirably carried out by the friction stir welding method. When manufacturing the semiconductor device 2 shown in FIG. 6, it is possible to manufacture the semiconductor device 2 by a similar method to that described above.

### Embodiments

Next, the embodiments of the semiconductor device according to the present invention are described, by comparing with a Comparative Example.

### COMPARATIVE EXAMPLE

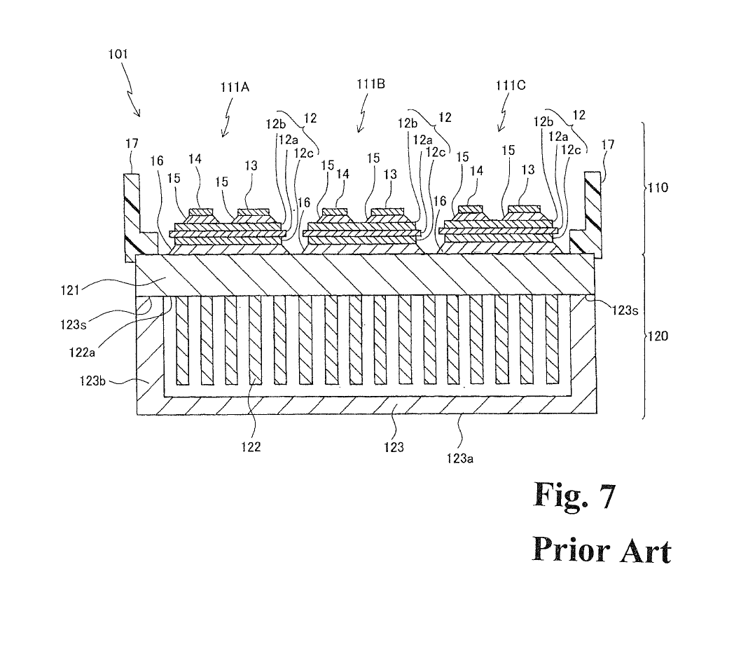

A Comparative Example which is a conventional semiconductor device is depicted in cross-sectional view in FIG. 7. In the semiconductor device 101 shown in FIG. 7, the semiconductor module 110 has a structure including a total of six circuit element sections in three rows in the perpendicular direction, each row having two circuit element sections arranged in the direction of flow of the coolant between the fins 122, on the cooler 120. FIG. 7 shows a cross-sectional view, and therefore the three circuit element sections 111A to 111C of the circuit element sections are depicted. The composition of these circuit element sections 111A to 111C is the same as that of the circuit element sections 11A to 11C according to the embodiment of the present invention shown in FIG. 2, and in FIG. 7, the same reference numerals as FIG. 2 are assigned, and duplicated description of the corresponding composition is omitted below.

The semiconductor device 100 in FIG. 7 has a structure in which the heat radiating substrate 121 and the case 123 are sealed by a sealing member 123s, and an aluminum material is employed respectively for same. Four types of heat radiating substrate 121 were prepared, each having a uniform thickness of 5 mm, 3.5 mm, 2.5 mm and 1.5 mm. Furthermore, when using a sealing member 123s, there is a limit on the material which can be used for the heat radiating substrate 121, and therefore an aluminum material having a thermal conductivity of 170 W/mk is used for each. Moreover, taking account of deformation and assembly tolerances, the clearance C between the front ends of the fins 122 and the case 123 was set at 1.5 mm.

Furthermore, due to the design of the case 123, a drift occurs in the flow rate distribution of the coolant flowing between the plurality of arranged fins 122, but it is possible to modify the inlet and/or the outlet (not illustrated) provided in the case 123, so as to achieve a uniform flow.

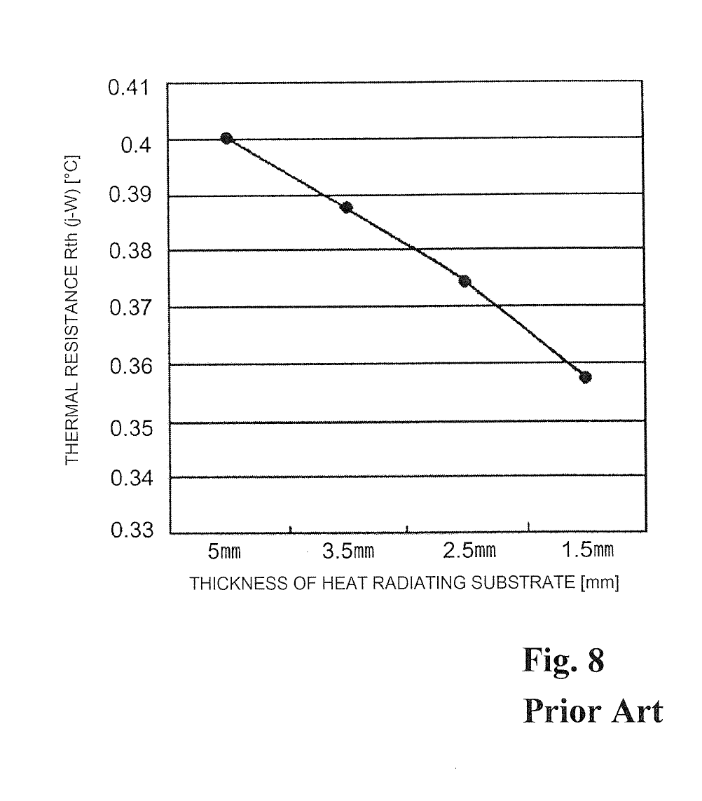

The heat generating temperatures of the semiconductor elements 13 and 14 when specific operating conditions were applied to the semiconductor elements 13 and 14 of the circuit element sections of the semiconductor device 100 were compared by a thermal fluid simulation using the above-mentioned heat radiating substrates 121 of four types having thicknesses of 5 mm, 3.5 mm, 2.5 mm and 1.5 mm. FIG. 8 shows the results.

FIG. 8 shows the results of comparing the thermal resistance between the junction temperature in the upper portions of the semiconductor elements 13 and 14 and the liquid temperature at the inlet, under steady conditions where antifreeze liquid was circulated uniformly at a flow rate of 10 1/min. and a uniform loss was applied. According to these results, it is possible to lower the thermal resistance by 10%, by reducing the thickness of the heat radiating substrate 121 to 1.5 mm. The thermal conductivity of the material of the heat radiating substrate 121 is 170 W/mk, which is a high thermal conductivity compared to the material of the insulating substrate, and the solder material, etc., but thermal conduction in the height direction is dominant compared to thermal diffusion, and this is inferred to be the reason why this result is obtained. Moreover, by reducing the thickness of the heat radiating substrate 121, it is possible to reduce the overall height of the base, which is the height from the upper surface of the heat radiating substrate 121 to the front end of the fins 22, without altering the height of the fins 22, and therefore the overall volume of the cooler can be reduced.

### Embodiment

As a comparison with the Comparative Example described above, the embodiment is described here as a preferred example of a cooler 20 in which the heat radiating substrate 21 and the case 23 are integrated in order to improve the heat radiating properties of the cooler 20 for the semiconductor module 10. The basic structure is similar to the structure shown in FIG. 1, and a composition omitting the sealing member is achieved by mechanical bonding.

In the Comparative Example described above, the heat radiating substrate 121 and the case 123 are sealed by a sealing member. This sealing member is, for example, an O-ring or a metal gasket. When this sealing member is used, there are limits on the strength (hardness) and thickness which can be demanded of the material of the heat radiating substrate, in order to ensure sealing performance (liquid-tightness). In particular, the type of material may govern the thermal conductivity, and it has been difficult to achieve both the strength and high thermal conductivity. In the case of an aluminum member, the use of a material having a thermal conductivity of approximately 170 W/mk has been inevitable.

Therefore, in the embodiment, mechanical bonding, for example, a thermal diffusion method or a friction stir welding method, or the like, is employed. Consequently, it is possible to omit the sealing member, and a material having a thermal conductivity of 200 W/mk or greater can be used for the heat radiating substrate 21, the thickness can be reduced, and therefore heat radiation can be increased. As well as mechanical bonding, it is also possible to bond by brazing.

Moreover, by integrating the heat radiating substrate 21 and the case 23, there is reduced thermal deformation and spreading upon application of pressure in the clearance C between the front ends of the fins 22 and the case 23, the coolant can be utilized efficiently, and the gaps allowed for assembly, and the like, can be reduced.

Moreover, by omitting the sealing member, it is possible to cut the number of assembly processes, and to reduce the steps requiring caution with respect to the surface roughness of the sealing surfaces, which is beneficial from the perspective of costs.

Here, the clearance C and the effect in improving the thermal conductivity of the heat radiating substrate 21 were compared by a thermal fluid simulation, using clearances of three levels: 1.5 mm; 0.5 mm; and 0 mm, and using thermal conductivities of two levels: 170 W/mk; and 210 W/mk. The heat radiating structure compared here had a heating radiating substrate thickness in the cooling section of 2.5 mm, and a uniform fin height of 10 mm, and the coolant conditions, and other conditions, were the same as in the Comparative Example.

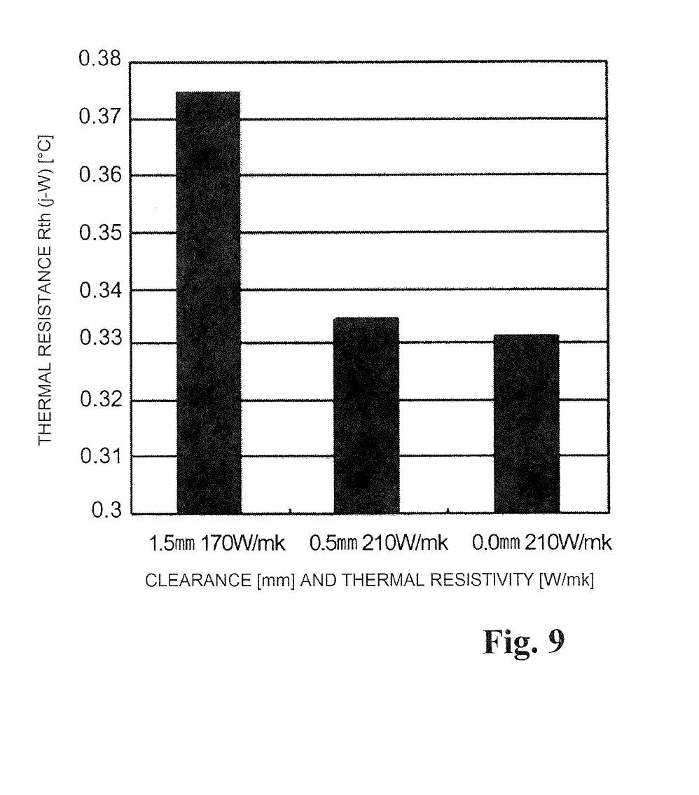

As shown in FIG. 9, it was confirmed that, in addition to the effect of improving thermal conductivity, by controlling the clearance C between the fin front end sections and the case, and making efficient use of the coolant, the thermal resistance based on the junction temperature and the coolant temperature at the position of the inlet was improved by approximately 12%. When the first embodiment, in which the clearance was 0.5 mm, was compared with the second embodiment, in which the clearance was 0 mm, no major difference was observed in the effects of the clearance C, since the clearance C was narrower than the gaps between the fins 22 and therefore the coolant did not readily escape into the clearance region, but an improvement of 20% to 30% over the Comparative Example was observed in the flow rate of the coolant flowing between the fins in the central height portion of the fins and the prior art configuration.

In this way, modifying the material of the heat radiating substrate and controlling the clearance C have beneficial effects which are obtained by bonding the case 23 and the heat radiating substrate 21, either completely or partially, but these effects are not limited to heat radiating properties alone, and taking account also of the effects on reliability of the thermal stress created by this heat, the structure also achieves increased strength due to the integrated composition.

### EXPLANATION OF REFERENCE NUMERALS

1 semiconductor device

10 semiconductor module

11A, 11B, 11C circuit element section

12 insulating substrate

12a insulating layer

12b, 12c conducting layer

13, 14 semiconductor element

15, 16 bonding layer

17 resin case

20 cooler

21 heat radiating substrate

22 fin

22a fin base material

23 case

23b side wall

23c inlet

23d outlet

23e coolant inlet flow channel

23f coolant discharge flow channel

23g cooling flow channel

23k cutaway

12 insulating substrate

40 inverter circuit

41 three-phase AC motor

C clearance

What is claimed is:

1. A semiconductor device comprising:
an insulating substrate;
a semiconductor element mounted on the insulating substrate; and
a cooler cooling the semiconductor element, and including:
a heat radiating substrate bonded to the insulating substrate;
a plurality of fins provided on a surface, opposite to a surface bonded with the insulating substrate, of the heat radiating substrate; and
a case accommodating the fins, and including an inlet and an outlet for a coolant,
wherein upper end portions of side walls of the case includes cutaways to arrange end portions of the heat radiating substrate so that the heat radiating substrate is liquid-tightly bonded to the case.

2. The semiconductor device according to claim 1, wherein the heat radiating substrate is friction stir welded to the case.

3. The semiconductor device according to claim 1, wherein the heat radiating substrate is made from a material having a thermal conductivity equal to or greater than that of the case.

4. The semiconductor device according to claim 1, wherein the fins have a shape selected from a plate shape and a pin shape.

5. The semiconductor device according to claim 1, wherein front ends of the fins are arranged proximately to a bottom surface of the case.

6. A method for manufacturing a semiconductor device, comprising:
preparing the semiconductor device including an insulating substrate, a semiconductor element mounted on the insulating substrate, and a cooler cooling the semiconductor element and having a heat radiating substrate, a plurality of fins, and a case,
forming cutaways in upper ends of side walls of the case of the cooler; and
arranging end portions of the heat radiating substrate in the cutaways of the case to liquid-tightly bond the heat radiating substrate and the case of the cooler.

7. The method for manufacturing a semiconductor device according to claim 6, wherein the liquid-tight bonding between the heat radiating substrate and the case is carried out by friction stir welding.
